(19) United States
(12) Patent Application Publication
(10) Pub. No.: US 2020/0057477 A1
(43) Pub. Date: Feb. 20, 2020

(54) NOTEBOOK COMPUTER D-CASE VAPOR CHAMBER

(71) Applicant: Google LLC, Mountain View, CA (US)

(72) Inventors: James Cooper, Sunnyvale, CA (US); Kenneth Ryan Loo, San Jose, CA (US); Igor Markovsky, Sunnyvale, CA (US)

(21) Appl. No.: 16/103,265

(22) Filed: Aug. 14, 2018

(51) Int. Cl. G06F 1/20; H05K 7/20; G06F 1/16

(52) U.S. Cl. CPC G06F 1/203; G06F 2200/201; G06F 1/1616; H05K 7/20336

(57) ABSTRACT

Techniques of managing heat within an electronic device include providing a vapor chamber as an external surface of an electronic device. For example, when the electronic device includes a thin notebook computer (e.g., an “ultrabook”), the vapor chamber may be, in its entirety or at least a part of, the d-case (i.e., the bottom cover or exterior surface of the laptop, opposite the keyboard and/or trackpad when the notebook computer is open). Such a vapor chamber may be very thin (as thin as 0.3 mm), while being about 50% more stiff and 50× more thermally conductive as aluminum, which may be used as the d-case in conventional notebook computers.

### TECHNICAL FIELD

This description relates to heat transport within electronic devices.

### BACKGROUND

Electronic devices such as laptop computers and tablet computers generate a significant amount of heat. Typically, this heat generated by a device is emitted out of the body of the device in the vicinity of a heat-generating mechanism (e.g., a CPU).

### SUMMARY

In one general aspect, an electronic device can include a vapor chamber having a first wall and a second wall opposite the first wall, a first external surface including an input device, a second external surface opposite the first external surface, the second external surface including the second wall of the vapor chamber, and a heat source between the first external surface and the second external surface, the vapor chamber being configured to remove heat from the heat source, the vapor chamber including: an evaporator surface portion at which heat is removed from the heat source to convert a liquid into a gas; a condensing surface portion at which the gas is cooled back into a cooled liquid; and a wick configured to return the cooled liquid back to the evaporating surface portion.

The details of one or more implementations are set forth in the accompanying drawings and the description below. Other features will be apparent from the description and drawings, and from the claims.

### BRIEF DESCRIPTION OF THE DRAWINGS

FIG. 1A is a diagram that illustrates a side view of an example electronic device in which improved techniques described herein may be implemented.

FIG. 1B is a diagram that illustrates details of the example vapor chamber included in the electronic device in which improved techniques described herein may be implemented.

FIG. 2A is a diagram that illustrates an example arrangement in which an interior surface of a vapor chamber is placed in direct contact with a heat source.

FIG. 2B is a diagram that illustrates an example arrangement in which an interior surface of a vapor chamber is placed in thermal contact with a heat source via a layer of thermal material.

FIG. 3 is a flow chart that illustrates an example method of forming a vapor chamber shown in FIGS. 1A and 1B.

FIG. 4 is a diagram that illustrates an example sheet material from which a vapor chamber may be formed according to the improved techniques.

FIG. 5 illustrates an example of a computer device and a mobile computer device that can be used with circuits described here.

### DETAILED DESCRIPTION

As mentioned above, conventional techniques of managing heat within an electronic device involve emitting heat out of the body of the electronic device in the vicinity of the heat-generating mechanism. In this way, however, the electronic device will have heat poorly distributed over its body. For example, a laptop generates heat in its base near its CPU, leaving the display cold. It is desirable to distribute heat throughout a device more equitably. A uniformly-heated device may use less power and is more comfortable for the user. In addition, a device that is uniformly-heated may have a lower maximum surface temperature than a device that concentrates the heat emission in one part of the surface, enabling the device to comply more readily with regulations regarding maximum surface temperatures of exterior metal surfaces.

In accordance with the implementations described herein and in contrast with the above-described conventional techniques of managing heat generated within an electronic device, improved techniques include integrating a vapor chamber into an external surface of an electronic device such that the electronic device and the vapor chamber share a common wall. For example, when the electronic device is a thin notebook computer (e.g., an “ultrabook” or “chromebook”), the vapor chamber may be at least a part of, the d-case (i.e., the bottom cover or exterior surface of the notebook computer, opposite the keyboard and/or trackpad when the notebook computer is open). Such a vapor chamber may be very thin (as thin as 0.3 mm), while being about 50% more stiff and 50× more thermally conductive than aluminum, which may be used as the d-case in conventional notebook computers.

In this way, the vapor chamber can provide an effectively isothermal base for the notebook computer. This may provide a significant boost in processing power of the device, without increasing the external surface temperature of the notebook computer, as compared with a conventionally cooled device. Such a boost in power without increasing surface temperature is also possible for other types of electronic devices such as tablet computers.

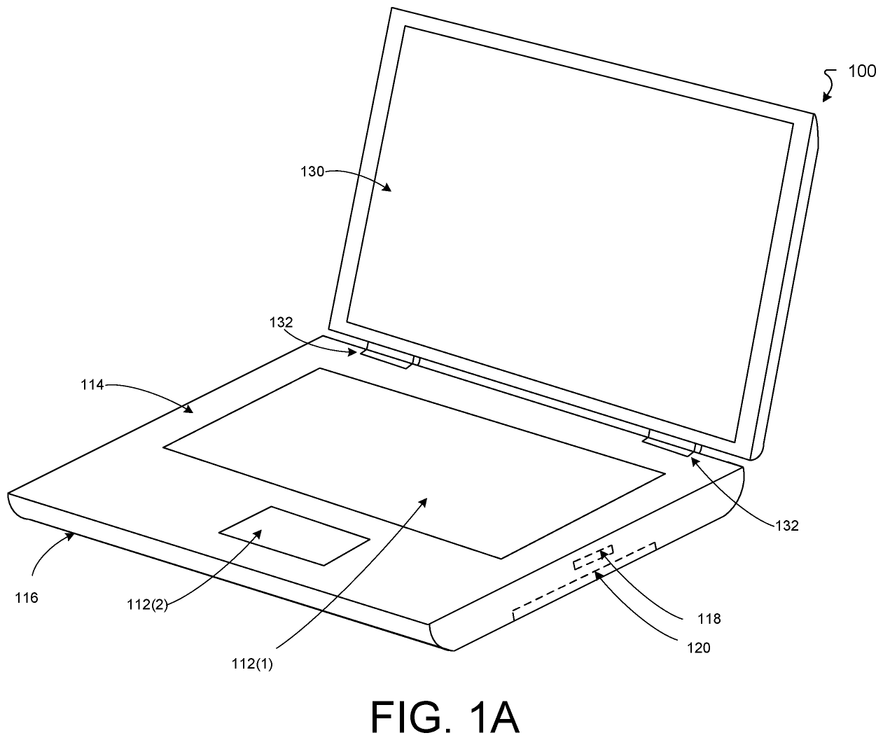

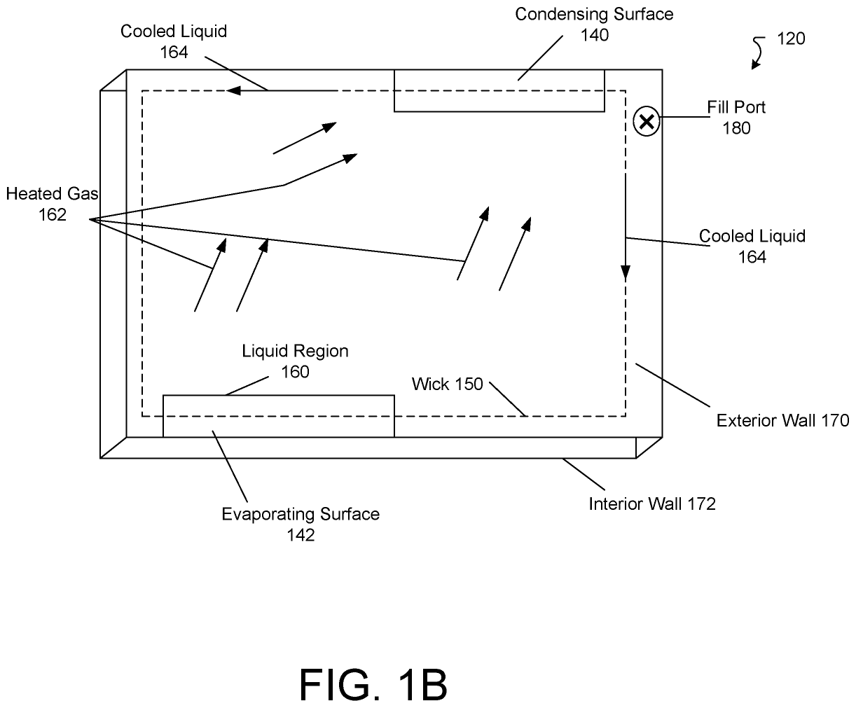

FIG. 1A is a diagram that illustrates a side view of an example notebook computer 100 in which the above-described improved techniques may be implemented. As shown, in FIG. 1, the example notebook computer 100 includes a base portion 110, a monitor portion 130, and a hinge 132.

As shown in FIG. 1A, the base portion 110 provides the processing power that generates output to be displayed on the monitor portion 130. The base portion 110 includes a first external surface 114 and a second external surface 116.

Between these external surfaces 114 and 116, there is a heat source 118. In some implementations, the heat source 118 includes one or more processing units. In some implementations, the one or more processing units 118 includes a central processing unit (CPU). In some implementations, the one or more processing units 118 includes a graphical processing unit (GPU). In some implementations, the one or more processing units 118 includes other types of processors such as application-specific integrated circuits (ASICs), field-programmable gate arrays (FPGAs), graphics processing units (GPUs) and the like.

Depending on the type of processing units are used in the one or more processing units 118, as well as other factors such as clock speed, power consumption, etc., the one or more processing units 118 produce a significant amount of heat within the base portion 110. Without a way to distribute the heat evenly over the surfaces 114 and 116, the notebook computer 100 may get too hot to operate unless the processing unit 118 are not operated above a certain performance level (e.g., slower than threshold clock speed). For example, an Intel® Core i7-920XM processor operating at 2.0 GHz is rated at 55 W of thermal design power (TDP). At this TDP rating, the maximum allowable temperature on the surfaces of a notebook computer may be exceeded in some devices.

As shown in FIG. 1A, the base portion 110 also includes a vapor chamber 120. As illustrated, in some implementations, the vapor chamber 120 can provide at least a portion of the external surface 116. In some implementations, an exterior surface of the vapor chamber 120 is integrated into the external surface 116. In some implementations, the vapor chamber 120 is part of a d-case for the notebook computer 100. In such implementations, by making the vapor chamber 120 serve as part of the d-case of the notebook computer 100, the vapor chamber 120 can act as an effective isothermal surface and therefore lower the maximum temperature on the surface of the notebook computer 100. This would allow for the notebook computer 100 to be operated at a higher performance level than in conventional configurations. In this implementation, the vapor chamber 120 would have a length and width of a base of a typical laptop, e.g., 15-20 cm by 10-20 cm.

The vapor chamber 120 is configured to absorb heat from the heat source 118 and dissipate the heat such heat is spread across the surfaces of the vapor chamber 120. When the vapor chamber 120 functions as the d-case of the notebook computer 100, the maximum surface temperature of the notebook computer 100 is significantly reduced while the heat source 118 (in the form of a CPU) runs software applications. Further details about the vapor chamber 120 are described with respect to FIG. 1B.

In some implementations, the above-described vapor chamber 120 may be similarly integrated into a back surface of a tablet computer. In the case of a tablet computer, the input device is a touch screen, and the vapor chamber would be integrated into the back surface opposite the touch screen.

FIG. 1B is a diagram that illustrates example details of the vapor chamber 120. The vapor chamber 120, as shown in FIG. 1B, includes an evaporating surface 142, a condensing surface 140, a wick 150, a liquid region 160 that may contain a liquid, an exterior wall 170, an interior wall 172, and a fill port 180.

The vapor chamber 120 works by using the heat generated by the heat source 118 (FIG. 1A) to evaporate a liquid in a liquid region 160 into a heated gas 162 at an evaporating surface 130. The vapor chamber 120 may then remove heat from the heated gas 162 at the condensing surface 140 to form the liquid. The liquid may then travel, e.g., by capillary action, along the liquid back to the liquid region 160, where the liquid may again be heated.

The evaporating surface 142 is configured to use heat from the heat source 118 to boil liquid in the liquid region 160 into a gas phase in the form of the heated gas 162. In some implementations, the evaporating surface 142 is made from thermally conductive materials to allow heat to pass through from the heat source 118. In some implementations, the liquid region 160 is adjacent to the evaporating surface 142.

The liquid contained in the liquid region 160 may depend on the material from which the vapor chamber 120 is constructed. In one example, when the interior of the chamber 120 includes copper, the liquid may include water. In another example, when the interior of the chamber includes aluminum, titanium, or steel, the liquid may include ammonia or water. In some implementations, however, the material from which the vapor chamber 120 is constructed includes steel. By using a material like steel, the stiffness of the walls 170 and 172 may be increased by as much as 50%, as compared with walls constructed of aluminum and having the same dimensions.

The condensing surface 140 is configured to receive heat from heated gas 162 and dissipate the heat out of the vapor chamber 120. The heated gas 162 then condenses back into the liquid and forms on a wick 150. In some implementations, the condensing surface 140 is made from thermally conductive materials to allow heat to pass through to a cooler region. For example, the vapor chamber 120 can form part of a d-case of the notebook computer 100. In this case, the condensing surface 140 may output heat to the environment containing the electronic device 100.

As shown in FIG. 1B, the condensing surface 140 is placed opposite the evaporating surface 142 within the vapor chamber 120. However, it should be appreciated that the evaporating surface 142 and the condensing surface 140 may be placed anywhere within the vapor chamber 120.

The wick 150 is configured to deliver the liquid formed by the condensation of the heated gas 162 at the condensing surface 140 to the evaporating surface 142. The delivery of the liquid may be achieved through capillary action along the wick 150. In some implementations, the wick 150 may be constructed from sintered copper. As shown in FIG. 1, the wick 150 can be located along a perimeter of the vapor chamber 120. However, in some implementations, the wick 150 may be located close to, or at, the exterior wall 170. In still other implementations, the wick 150 may be located close to, or at, the interior wall 172.

The fill port 180 can be configured to introduce and/or remove the liquid into the vapor chamber 120. As shown in FIG. 1B, the fill port 180 is attached to the exterior wall 170 and points outward, away from the interior wall 172.

The thickness of the vapor chamber 120 (i.e., the distance between the exterior wall 170 and interior wall 172) may, in some implementations, be small in order to support small notebook computers. In some implementations, the thickness of the vapor chamber 120 is less than 1 mm. In some implementations, the thickness of the vapor chamber is less than 0.8 mm. In some implementations, the thickness of the vapor chamber is less than 0.5 mm (e.g., about 0.3 mm).

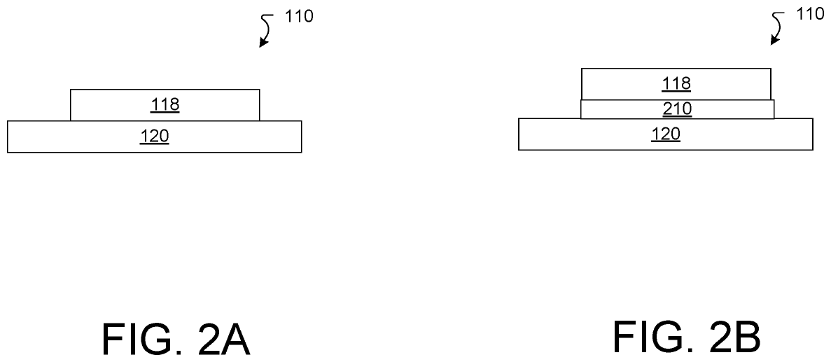

FIGS. 2A and 2B are diagrams that illustrate various placements of the heat source 118 with respect to the vapor chamber 120. In the various cases described in FIGS. 2A and 2B, the vapor chamber 120 is in some sort of thermal contact with the heat source 118.

In some implementations, the vapor chamber 120 and the heat source 118 are in thermal contact when a heat transfer coefficient is greater than a threshold, e.g., 2000 W/m²/K. The heat transfer coefficient in thermodynamics is the proportionality constant between the heat flux and the thermodynamic driving force for the flow of heat (i.e., a temperature difference between the heat source 118 and the vapor chamber 120).

FIG. 2A illustrates an implementation in which the vapor chamber 120 is in direct thermal contact with the heat source 118. In this implementation, “direct” thermal contact implies direct contact between the interior wall 172 of the vapor chamber 120 and a surface of the heat source 118. The heat source 118 has, in some implementations, a footprint that is a small fraction of the cross-sectional area of the vapor chamber 120. In this implementation, the heat source 118 may be in contact with the vapor chamber 120 at the evaporating surface 142 (FIG. 1B). In this way, the heat generated by the heat source 118 may immediately generate the hot gases necessary to dissipate the heat at the condensing surface 140.

FIG. 2B illustrates an implementation in which the vapor chamber 120 is in indirect thermal contact with the heat source 118. Between the vapor chamber 120 and the heat source 118 is a layer of thermal interface material 210. The layer of thermal interface material 210 is a thermal conductor through which heat from the heat source 118 is transported to the interior wall 170 of the vapor chamber 120. In some implementations, the layer of thermal material 210 is an air gap. In some implementations, the layer of thermal material 210 is thermal grease. In some implementations, the layer of thermal material 210 is a thermal pad having a thermal conductivity between 1 and 10 W/m/K, in some implementations between 1 and 3 W/m/K. In some implementations, the thickness of the layer of thermal material 210 depends on the thermal material. For example, in some implementations, a layer of thermal grease is less than 0.1 mm. In some implementations, a thermal pad has a thickness of less than 1.0 mm.

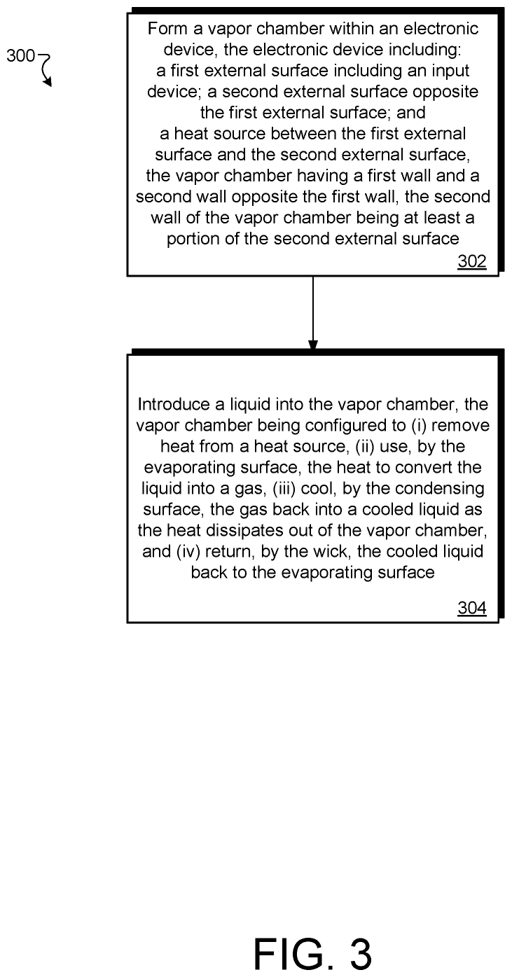

FIG. 3 is a flow chart that illustrates an example method 300 of implementing the improved techniques shown in FIGS. 1A and 1B.

At 302, a vapor chamber is formed within an electronic device (e.g., the notebook computer 100). The electronic device includes a first external surface including an input device; a second external surface opposite the first external surface; and a heat source between the first external surface and the second external surface. The vapor chamber has a first wall and a second wall opposite the first wall. The second wall of the vapor chamber is at least a portion of the second external surface. The vapor chamber is configured to remove heat from the heat source.

At 304, a liquid is introduced into the vapor chamber. The vapor chamber is configured to (i) remove heat from a heat source, (ii) use, at the evaporating surface, the heat to convert the liquid into a gas, (iii) cool, at the condensing surface, the gas back into a cooled liquid as the heat dissipates out of the vapor chamber, and (iv) return, by the wick, the cooled liquid back to the evaporating surface.

In some implementations, the electronic device is a notebook computer, the heat source is a central processing unit (CPU), and the input device includes a keyboard. In some implementations, the vapor chamber is in direct thermal contact with the CPU. In some implementations, the vapor chamber is in thermal contact with the CPU via a layer of thermal material. In some implementations, the thermal material is thermal grease. In some implementations, the thermal material is a thermal pad having a thermal conductivity between 1 and 3 W/m/K. In some implementations, the vapor chamber is a d-case of the notebook computer.

In some implementations, each of the first wall and the second wall of the vapor chamber is made of a material having a stiffness greater than that of aluminum. In some implementations, each of the first wall and the second wall of the vapor chamber is made of a material having a thermal conductivity greater than that of aluminum. In some implementations, each of the first wall and the second wall of the vapor chamber includes steel.

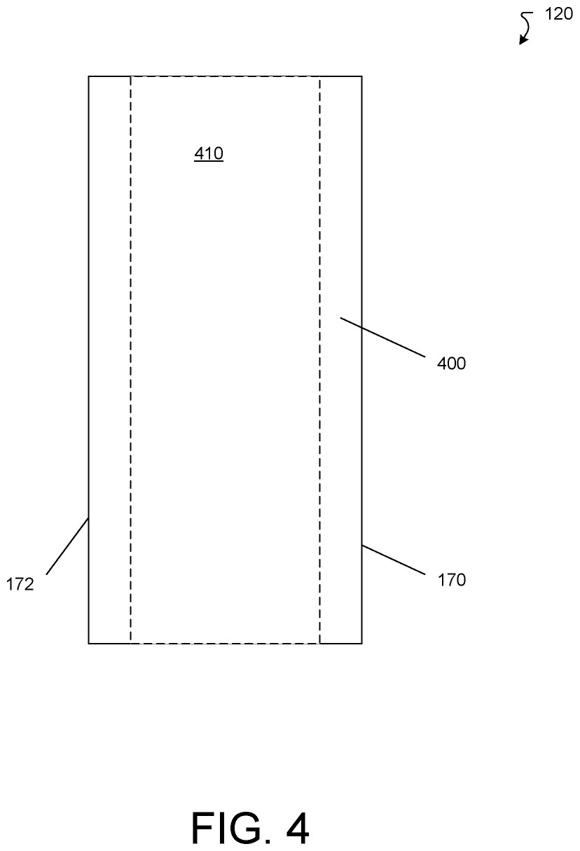

FIG. 4 is a diagram that illustrates an example layer of material 400 used to form the vapor chamber 120 according to the improved techniques described herein.

As shown in FIG. 4, the vapor chamber 120 is formed from the layer of material 400 by removing a portion of the interior of the material 400 to form the exterior wall 170 and the interior wall 172. In some implementations, the layer of material 400 is a piece of sheet metal. In some implementations, the sheet metal is made from steel. In some implementations, the sheet metal is made from copper and/or titanium. In this way, the vapor chamber 120 that results from the removal of the material 410 has the desired thickness and stiffness.

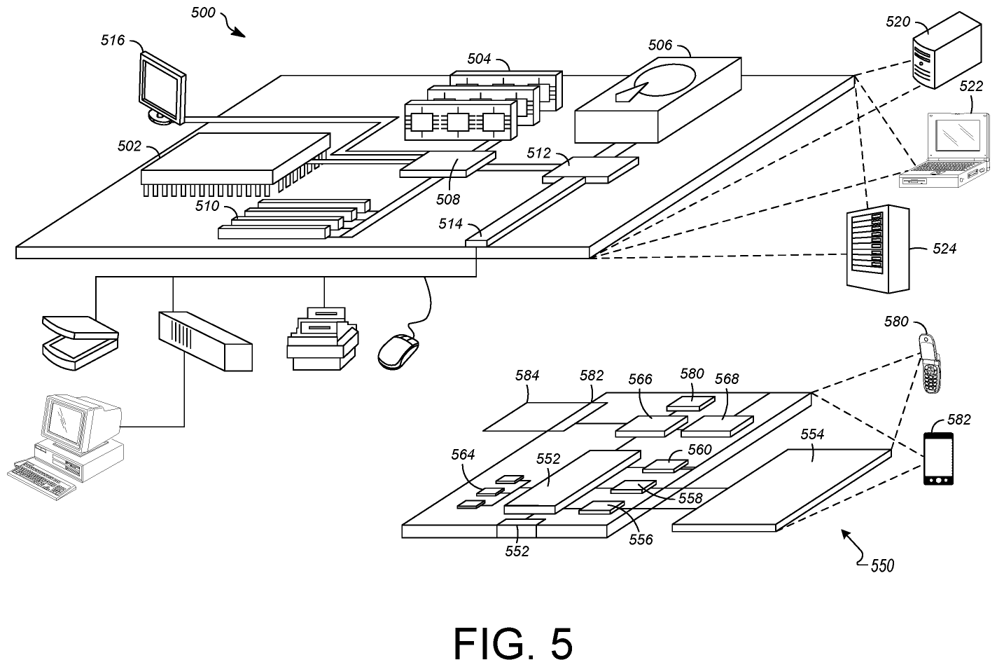

FIG. 5 illustrates an example of a generic computer device 500 and a generic mobile computer device 550, which may be used with the techniques described here.

As shown in FIG. 5, computing device 500 is intended to represent various forms of digital computers, such as laptops, personal digital assistants, tablets, gaming devices, and other appropriate computers in which the techniques described herein can be implemented. Computing device 550 is intended to represent various forms of mobile devices, such as personal digital assistants, cellular telephones, smart phones, and other similar computing devices. The components shown here, their connections and relationships, and their functions, are meant to be exemplary only, and are not meant to limit implementations of the inventions described and/or claimed in this document.

Computing device 500 includes a processor 502, memory 504, a storage device 506, a high-speed interface 508 connecting to memory 504 and high-speed expansion ports 510, and a low speed interface 512 connecting to low speed bus 514 and storage device 506. Each of the components 502, 504, 506, 508, 510, and 512, are interconnected using various busses, and may be mounted on a common motherboard or in other manners as appropriate. The processor 502 can process instructions for execution within the computing device 500, including instructions stored in the memory 504 or on the storage device 506 to display graphical information for a GUI on an external input/output device, such as display 516 coupled to high speed interface 508. In other implementations, multiple processors and/or multiple buses may be used, as appropriate, along with multiple memories and types of memory. Also, multiple computing devices 500 may be connected, with each device providing portions of the necessary operations (e.g., as a server bank, a group of blade servers, or a multi-processor system).

The memory 504 stores information within the computing device 500. In one implementation, the memory 504 is a volatile memory unit or units. In another implementation, the memory 504 is a non-volatile memory unit or units. The memory 504 may also be another form of computer-readable medium, such as a magnetic or optical disk.

The storage device 506 is capable of providing mass storage for the computing device 500. In one implementation, the storage device 506 may be or contain a computer-readable medium, such as a floppy disk device, a hard disk device, an optical disk device, or a tape device, a flash memory or other similar solid state memory device, or an array of devices, including devices in a storage area network or other configurations. A computer program product can be tangibly embodied in an information carrier. The computer program product may also contain instructions that, when executed, perform one or more methods, such as those described above. The information carrier is a computer- or machine-readable medium, such as the memory 504, the storage device 506, or memory on processor 502.

The high speed controller 508 manages bandwidth-intensive operations for the computing device 500, while the low speed controller 512 manages lower bandwidth-intensive operations. Such allocation of functions is exemplary only. In one implementation, the high-speed controller 508 is coupled to memory 504, display 516 (e.g., through a graphics processor or accelerator), and to high-speed expansion ports 510, which may accept various expansion cards (not shown). In the implementation, low-speed controller 512 is coupled to storage device 506 and low-speed expansion port 514. The low-speed expansion port, which may include various communication ports (e.g., USB, Bluetooth, Ethernet, wireless Ethernet) may be coupled to one or more input/output devices, such as a keyboard, a pointing device, a scanner, or a networking device such as a switch or router, e.g., through a network adapter.

The computing device 500 may be implemented in a number of different forms, as shown in the figure. For example, it may be implemented as a standard server 520, or multiple times in a group of such servers. It may also be implemented as part of a rack server system 524. In addition, it may be implemented in a personal computer such as a laptop computer 522. Alternatively, components from computing device 500 may be combined with other components in a mobile device (not shown), such as device 550. Each of such devices may contain one or more of computing device 500, 550, and an entire system may be made up of multiple computing devices 500, 550 communicating with each other.

Computing device 550 includes a processor 552, memory 564, an input/output device such as a display 554, a communication interface 566, and a transceiver 568, among other components. The device 550 may also be provided with a storage device, such as a microdrive or other device, to provide additional storage. Each of the components 550, 552, 564, 554, 566, and 568, are interconnected using various buses, and several of the components may be mounted on a common motherboard or in other manners as appropriate.

The processor 552 can execute instructions within the computing device 550, including instructions stored in the memory 564. The processor may be implemented as a chipset of chips that include separate and multiple analog and digital processors. The processor may provide, for example, for coordination of the other components of the device 550, such as control of user interfaces, applications run by device 550, and wireless communication by device 550.

Processor 552 may communicate with a user through control interface 558 and display interface 556 coupled to a display 554. The display 554 may be, for example, a TFT LCD (Thin-Film-Transistor Liquid Crystal Display) or an OLED (Organic Light Emitting Diode) display, or other appropriate display technology. The display interface 556 may comprise appropriate circuitry for driving the display 554 to present graphical and other information to a user. The control interface 558 may receive commands from a user and convert them for submission to the processor 552. In addition, an external interface 562 may be provided in communication with processor 552, so as to enable near area communication of device 550 with other devices. External interface 562 may provide, for example, for wired communication in some implementations, or for wireless communication in other implementations, and multiple interfaces may also be used.

The memory 564 stores information within the computing device 550. The memory 564 can be implemented as one or more of a computer-readable medium or media, a volatile memory unit or units, or a non-volatile memory unit or units. Expansion memory 574 may also be provided and connected to device 550 through expansion interface 572, which may include, for example, a SIMM (Single In Line Memory Module) card interface. Such expansion memory 574 may provide extra storage space for device 550, or may also store applications or other information for device 550. Specifically, expansion memory 574 may include instructions to carry out or supplement the processes described above, and may include secure information also. Thus, for example, expansion memory 574 may be provided as a security module for device 550, and may be programmed with instructions that permit secure use of device 550. In addition, secure applications may be provided via the SIMM cards, along with additional information, such as placing identifying information on the SIMM card in a non-hackable manner.

The memory may include, for example, flash memory and/or NVRAM memory, as discussed below. In one implementation, a computer program product is tangibly embodied in an information carrier. The computer program product contains instructions that, when executed, perform one or more methods, such as those described above. The information carrier is a computer- or machine-readable medium, such as the memory 564, expansion memory 574, or memory on processor 552, that may be received, for example, over transceiver 568 or external interface 562.

Device 550 may communicate wirelessly through communication interface 566, which may include digital signal processing circuitry where necessary. Communication interface 566 may provide for communications under various modes or protocols, such as GSM voice calls, SMS, EMS, or MMS messaging, CDMA, TDMA, PDC, WCDMA, CDMA2000, or GPRS, among others. Such communication may occur, for example, through radio-frequency transceiver 568. In addition, short-range communication may occur, such as using a Bluetooth, WiFi, or other such transceiver (not shown). In addition, GPS (Global Positioning System) receiver module 570 may provide additional navigation- and location-related wireless data to device 550, which may be used as appropriate by applications running on device 550.

Device 550 may also communicate audibly using audio codec 560, which may receive spoken information from a user and convert it to usable digital information. Audio codec 560 may likewise generate audible sound for a user, such as through a speaker, e.g., in a handset of device 550. Such sound may include sound from voice telephone calls, may include recorded sound (e.g., voice messages, music files, etc.) and may also include sound generated by applications operating on device 550.

The computing device 550 may be implemented in a number of different forms, as shown in the figure. For example, it may be implemented as a cellular telephone 580. It may also be implemented as part of a smart phone 582, personal digital assistant, or other similar mobile device.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

To provide for interaction with a user, the systems and techniques described here can be implemented on a computer having a display device (e.g., a CRT (cathode ray tube) or LCD (liquid crystal display) monitor) for displaying information to the user and a keyboard and a pointing device (e.g., a mouse or a trackball) by which the user can provide input to the computer. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The systems and techniques described here can be implemented in a computing system that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (“LAN”), a wide area network (“WAN”), and the Internet.

The computing system can include clients and servers. A client and server are generally remote from each other and typically interact through a communication network. The relationship of client and server arises by virtue of computer programs running on the respective computers and having a client-server relationship to each other.

A number of embodiments have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

1. An electronic device, comprising:
a first external surface including an input device,
a second external surface opposite the first external surface,
a heat source between the first external surface and the second external surface, and
a vapor chamber having a first wall and a second wall opposite the first wall, the first wall being located in between the first external surface and the second external surface, the second wall being integrated into the second external surface, the vapor chamber being in thermal contact with the heat source, the vapor chamber including:
an evaporator surface portion at which heat is removed from the heat source to evaporate a liquid into a gas;
a condensing surface portion at which the gas is condensed into a liquid; and
a wick configured to return the liquid to the evaporating surface portion,
wherein the electronic device includes a base portion and a monitor portion, the heat source includes a central processing unit (CPU), and the input device includes a keyboard, and
wherein the vapor chamber is in thermal contact with the CPU via a layer of thermal material.

2-4. (canceled)

5. The electronic device of claim 1, wherein the thermal material includes thermal grease.

6. The electronic device of claim 1, wherein the thermal material includes a thermal pad.

7. The electronic device of claim 1, wherein the thermal material includes a thermal pad having a thermal conductivity between 1 and 10 W/m/K.

8. The electronic device of claim 1, wherein the vapor chamber is at least part of a d-case of the base portion of the electronic device.

9. The electronic device of claim 1, wherein each of the first wall and the second wall of the vapor chamber includes a material having a Young's modulus greater than that of aluminum.

10. The electronic device of claim 9, wherein each of the first wall and the second wall of the vapor chamber includes steel.

11. A vapor chamber configured to remove heat from a heat source within an electronic device, the vapor chamber comprising:
a first wall;
a second wall opposite the first wall;
an evaporator surface portion at which heat is removed from the heat source to convert a liquid into a gas;
a condensing surface portion at which the gas is cooled back into a cooled liquid; and
a wick configured to return the cooled liquid back to the evaporating surface portion,
the second wall of the vapor chamber being integrated into an external surface of the electronic device,
wherein each of the first wall and the second wall of the vapor chamber include steel.

12. The vapor chamber of claim 11, the vapor chamber is formed by removing an interior portion of a layer of sheet metal to produce the first wall and the second wall.

13. The vapor chamber of claim 11, wherein the electronic device includes a base portion and a monitor portion and the heat source includes a central processing unit (CPU).

14. The vapor chamber of claim 13, wherein the vapor chamber is in thermal contact with the CPU via a layer of thermal material.

15. The vapor chamber of claim 13, wherein the vapor chamber is in thermal contact with the CPU.

16. The vapor chamber of claim 14, wherein the thermal material includes thermal grease.

17. The vapor chamber of claim 14, wherein the thermal material includes a thermal pad having a thermal conductivity between 1 and 3 W/m/K.

18. The vapor chamber of claim 13, wherein the vapor chamber is at least a part of a d-case of the base portion of the electronic device.

19-20. (canceled)

21. The electronic device of claim 1, wherein the wick of the vapor chamber is located at the second wall.

22. The vapor chamber of claim 11, wherein the wick is located at the first wall.
